(19) United States
(12) Patent Application Publication
(10) Pub. No.: US 2010/0224994 A1
(43) Pub. Date: Sep. 9, 2010

(54) Low Temperature Metal to Silicon Diffusion and Silicide Wafer Bonding

(75) Inventor: Changhan Yun, Cambridge, MA (US)

Correspondence Address: Sunstein Kann Murphy & Timbers LLP, 125 SUMMER STREET, BOSTON, MA, 02110-1618, US

(73) Assignee: ANALOG DEVICES, INC., Norwood, MA (US)

(21) Appl. No.: 12/398,774

(22) Filed: Mar. 5, 2009

(51) Int. Cl. H01L 23/06; H01L 21/30

(52) U.S. Cl. 257/741; 438/121; 257/E21.211; 257/E23.191

(57) ABSTRACT

A method of bonding two members includes forming a metal pad on a first member and a silicon pad on the second member, and coupling the pads at a temperature and pressure that will not damage features of the members, such as integrated circuitry or MEMS devices, but is sufficient to form a silicide bond. In various embodiments, the metal may be nickel and the silicon may be polysilicon.

### TECHNICAL FIELD

The present invention relates to bonding silicon to metal, and more particularly, to bonding semiconductor products to metal surfaces.

### BACKGROUND ART

It is known in the prior art to bond objects with various adhesives. In the art of semiconductor bonding, it is known to bond elements of a semiconductor product with, for example, a glass frit, solder, or by creating a conductive bond by way of interdiffusion or thermocompression of materials. The quality of a bond may be measured by, among other things, its strength, size (e.g., dimensions of the bonding material required to achieve a desired strength), the temperatures and pressures at which the bond must be formed, and the time it takes to fabricate the bond, among other factors.

Some semiconductor products may include features that may be adversely affected by high temperatures, such as integrated circuitry, or high pressures, such as micro-electromechanical systems (“MEMS”). Some prior art bonding methods, such as forming a metal-to-metal bond (e.g., Al—Al, Cu—Cu, or Au—Au), may require exposing the semiconductor product temperatures and/or pressures that are undesirably high in view of other requirements of the fabrication process, or may be unacceptably slow. A metal-silicon eutectic structure requires a processing temperature that may be undesirable in some applications (e.g., for aluminum-silicon, the eutectic temperature is approximately 577 degrees Celsius), and also has a lower bond strength than a silicide, and so must undesirably be larger than a silicide structure of similar strength.

FIG. 1 is a schematic cross-section illustrating a prior art bonding method using a glass frit to bond two members. To form a bond in assembly 100, a glass frit 103 is placed between the members 101 and 102, and the assembly 100 is heated, possibly to greater than 400 degrees Celsius.

FIG. 2 is a schematic cross-section illustrating a prior art bonding method using intermediate metal pads and solder, as shown in FIG. 6 of U.S. Pat. No. 6,297,072, entitled “Method of Fabrication of a Microstructure Having an Internal Cavity,” by Tilmans et al. A first member 201 may have a first metal pad 203, and a second member 202 may have a second metal pad 204. The first member 201 and the second member 202 may be bonded together to form assembly 200 by fabricating a solder layer 205 between the metal pad 203 and a metal pad 204. The metal pads 203 and 204 may include a seed layer at the boundary of the metal pad (203 and 204) and the member (201 and 202) to which it is attached.

FIG. 3 is a schematic cross-section illustrating a prior art bonding method using solder balls 304 to bond two members 301 and 302 to form assembly 300. The solder balls 304 may be fabricated to couple vias 303 in the respective members. One example of using solder balls to bond two members is presented in published US patent application, Pub. No. 2005/0127499 A1, published Jun. 16, 2005 and entitled “MEMS Device With Conductive Path Through Substrate,” by Harney et al. Bonds may also be formed using platinum silicide, tungsten silicide or titanium silicide.

FIG. 4 is a schematic cross-section illustrating a prior art bonding method in which a member 401 (such as an integrated circuit) is bonded to a lead frame 402 by solder balls 403 to form assembly 400. A potential shortcoming of using solder is that solder may not be environmentally friendly, and may also be a source of undesirable particles.

### SUMMARY OF THE INVENTION

In a first embodiment of the invention, a method provides a first semiconductor member having a nickel portion, and a second semiconductor member having a polysilicon (poly-crystalline silicon) portion. The first and second semiconductor members are oriented with respect to one another such that the nickel portion is in contact with the polysilicon portion. The arrangement is subjected to a temperature and a compressive force that are sufficient to form nickel silicide at the interface of the nickel portion and the silicon portion, so that the members become bonded. The nickel portion may be formed by electroless plating.

A method of bonding a first surface to a second surface involves providing a first surface having a nickel portion and a second surface having a silicon portion, contacting the nickel portion to the silicon portion, and then subjecting the interface of the two portions to both a temperature (in some embodiments, the temperature is no greater than about 450 degrees Celsius, although in some embodiments, lower temperatures are used, and some bonds are made at temperatures of about 300 degrees Celsius) and a compressive force, such that the temperature and compressive force are sufficient to form nickel silicide at the interface. In some embodiments, the temperature is less than 280 degrees Celsius. In fact, a nickel silicide may be formed at temperatures as low as 200 degrees Celsius.

In some embodiments, providing a first surface having a nickel portion involves forming a nickel portion on the first surface by a process of electroless plating, electroplating, physical vapor deposition (e.g., sputtering or evaporation) or chemical vapor deposition. Some embodiments include providing a first surface with an aluminum portion supported by the first surface, and forming the nickel portion substantially on the aluminum portion. Some embodiments include forming a layer of gold over at least part of the nickel portion, and some embodiments include forming the nickel portion on the first surface in a substantially oxygen-free environment.

Some embodiments may include a first surface or a second surface that is comprises a leadframe for a semiconductor die.

In some embodiments, providing a second surface having a silicon portion may include forming a silicon portion on the second surface if, for example, the second surface does not already have a suitable silicon portion. In some embodiments, such a silicon portion may be a polysilicon pad.

A method of fabricating a semiconductor structure includes providing a first member and fabricating a nickel pad on the first member, providing a semiconductor member, coupling the nickel pad to the second semiconductor member, and subjecting the nickel pad and the semiconductor member to a temperature less than a temperature at which other features of the semiconductor structure would be damaged (for example, in some embodiments, below about 300 degrees Celsius), where the temperature at least in part is sufficient to form a silicide at the interface of the nickel pad and the semiconductor member.

A semiconductor apparatus includes a silicon member, a coupling member having a surface; and nickel silicide bonding the surface of the coupling member to the silicon member.

### BRIEF DESCRIPTION OF THE DRAWINGS

The foregoing features of the invention will be more readily understood by reference to the following detailed description, taken with reference to the accompanying drawings, in which:

FIG. 1 is a schematic cross-section illustrating a prior art bonding method using a glass frit to bond two members.

FIG. 2 is a schematic cross-section illustrating a prior art bonding method using intermediate metal layers and solder.

FIG. 3 is a schematic cross-section illustrating a prior art bonding method using solder.

FIG. 4 is a schematic cross-section illustrating a prior art bonding method in which a member is bonded to a lead frame with solder.

FIG. 5 is a schematic cross-section of two members to be bonded illustrating an embodiment of the present invention.

FIG. 6 is a schematic cross-section of two members to be bonded illustrating an embodiment of the present invention.

FIG. 7 is a schematic cross-section of two members to be bonded illustrating an embodiment of the present invention.

FIG. 8A is a schematic cross-section of two members to be bonded illustrating an embodiment of the present invention.

FIG. 8B is a schematic cross-section of two members to be bonded illustrating an embodiment of the present invention.

FIG. 8C is a schematic cross-section of two members to be bonded as in FIG. 8A, and also including a silicon area opposite the nickel area.

FIG. 8D is a schematic cross-section of two members to be bonded as in FIG. 8B, and also including a silicon area opposite the nickel area.

FIG. 9 is a schematic cross-section of two members to be bonded illustrating an embodiment of the present invention.

FIG. 10A is a schematic cross-section of two members to be bonded illustrating an embodiment of the present invention.

FIG. 10B is a schematic cross-section of two members to be bonded illustrating an embodiment of the present invention.

FIG. 11 is a schematic illustration of an embodiment of the present invention in which an integrated circuit is to be bonded to a lead frame.

FIG. 12 is a flow chart of an embodiment of the present invention.

FIG. 13A is a schematic cross-section of a device fabricated according to an embodiment of the present invention.

FIG. 13B is a schematic cross-section of a device fabricated according to an embodiment of the present invention.

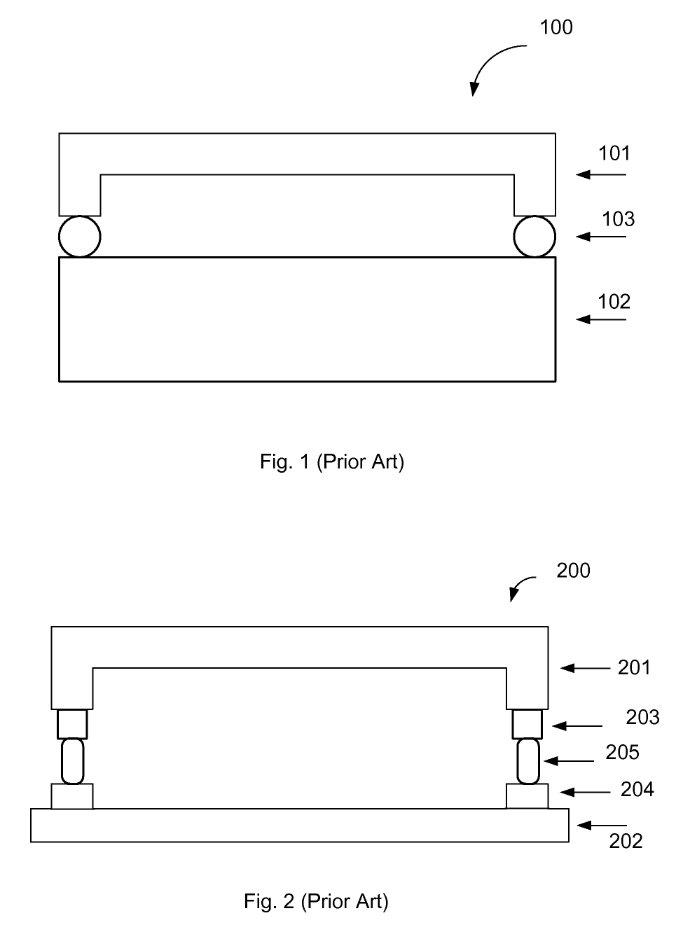

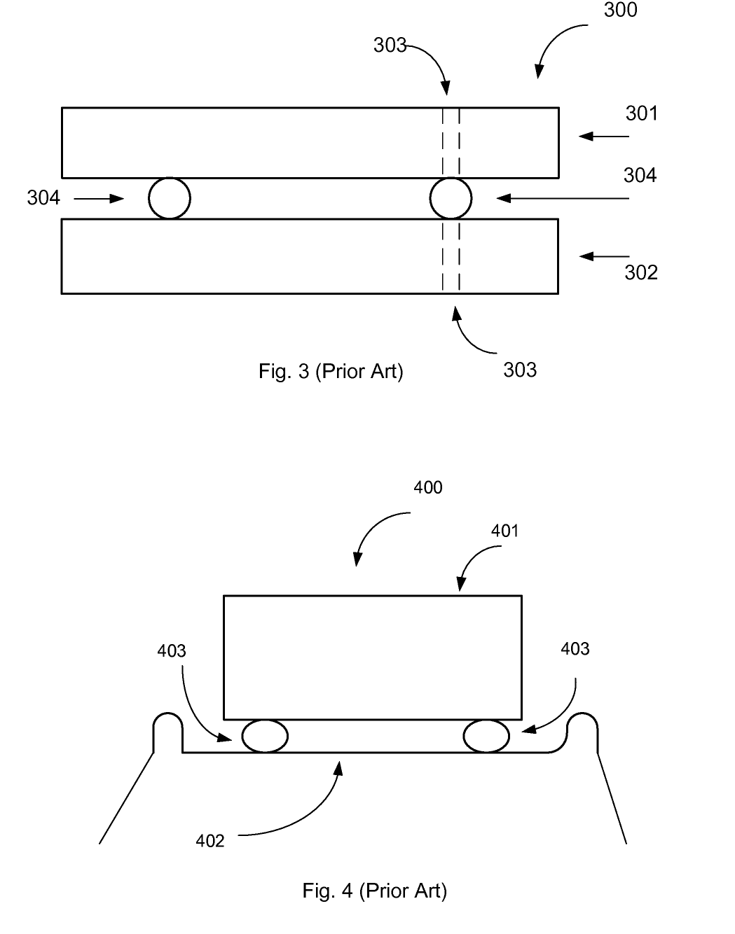

### DETAILED DESCRIPTION OF SPECIFIC EMBODIMENTS

In illustrative embodiments, a nickel silicide bonds a semiconductor member to another member. For example, a nickel silicide may bond a cap wafer to a device wafer. The nature of nickel silicide enables a strong bond at temperatures that do not affect certain heat sensitive components. Details are discussed below.

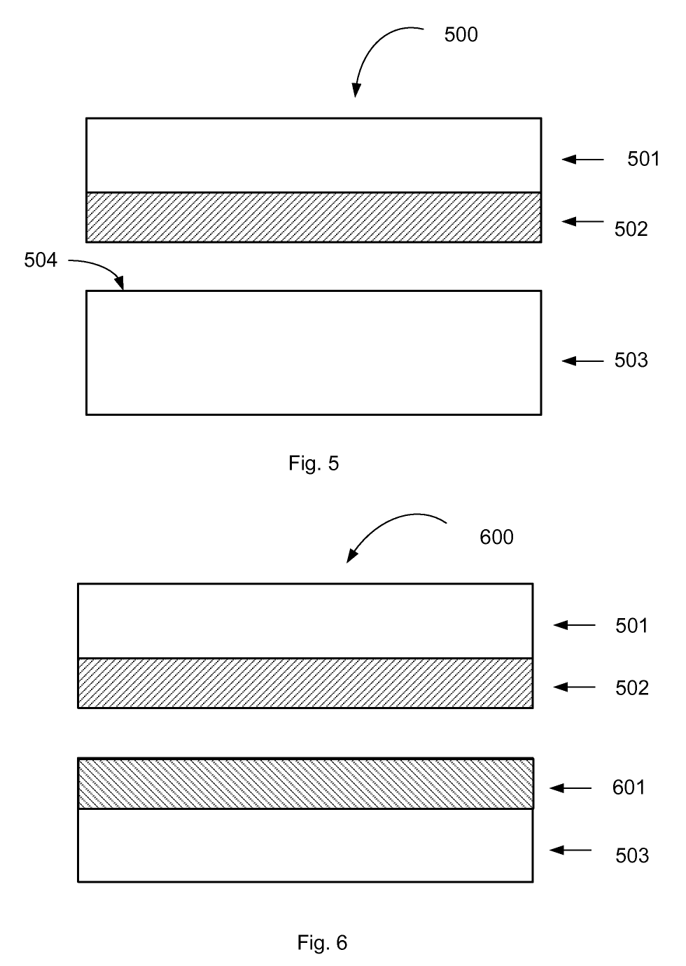

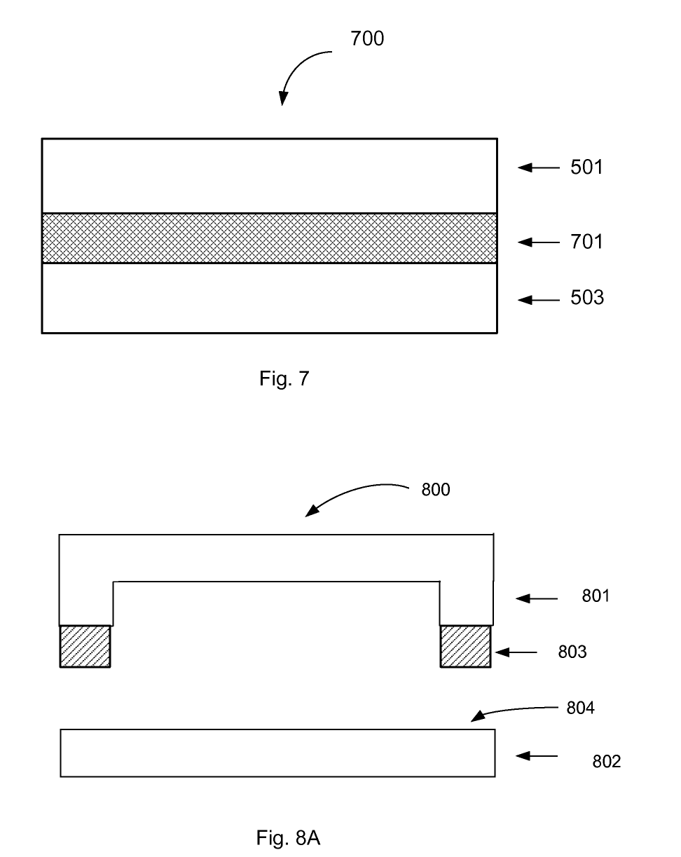

A cross-section 500 illustrating the bonding of two members according to one embodiment of the present invention is shown in FIG. 5. A first silicon wafer 501 includes nickel layer 502 on its bottom face. A second silicon wafer 503 has a top face 504 that faces the nickel layer 502. When the top face 504 of the second silicon wafer 503 is coupled to the nickel layer 502, at a temperature and under pressure, a nickel silicide is formed to bond the wafers, as illustrated as layer 701 in FIG. 7. In some embodiments, the bond may form a hermetic seal and/or the bond may also be conductive.

Forming a silicide requires subjecting the bonding location, and the semiconductor device, to elevated temperatures and pressures for some duration of time. Selecting the form of silicide to be used will depend, at least in part, on the limits of temperature and pressure to which the members being bonded can be subjected. For example, nickel enables use of relatively low temperatures and pressures to form a nickel silicide. When forming nickel silicide, if the temperature is greater than 300 degrees Celsius, then the nickel silicide will have two silicon atoms for each nickel atom (this may be known as “silicon rich”). However, if the temperature is less than 300 degrees Celsius, then the nickel silicide will have two nickel atoms for each silicon atom (this may be known as “nickel rich”). Those skilled in the art should be able to select the appropriate temperatures, pressures and times based on the type of bond desired. Nickel silicide may form under some conditions at temperatures below 280 degrees Celsius, and even as low as 200 degrees Celsius.

The silicide bonds may vary in strength, size (e.g., dimensions of the bonding area required to achieve a desired strength), and fabrication time, depending upon its atomic structure. Some prior art metals may not form sufficiently thick films for a suitable silicide bond. Also, depending on the metal used, some prior art silicides may not provide flexibility in the fabrication method. For example, some prior art methods may require fabrication by one or more of electroplating, physical vapor deposition (e.g., sputtering or evaporation), or chemical vapor deposition (“CVD”). Illustrative embodiments may form the nickel silicide by any of those methods, and preferably, electroless plating.

Illustrative embodiments of the present invention may involve formation of nickel silicide, although the invention is not limited to the use of nickel silicide. An advantage of the nickel-silicide bonding method is that it can be performed at lower temperatures (for example, in some embodiments, less than 300 degrees Celsius) and lower pressure (for example, in some embodiments, approximately 50 MPa) than some other metals. In this way, features of the members being bonded, such as integrated circuits or MEMS devices, may be spared exposure to higher temperatures and pressures.

In an alternate embodiment schematically illustrated in cross-section 600 of FIG. 6, the second wafer 503 may include a layer of polysilicon 601. When the polysilicon layer 601 is coupled to the nickel layer 502, at a temperature and under pressure, a nickel silicide is formed to bond the wafers, which may also be illustrated as layer 701 in FIG. 7.

Fabrication of a nickel portion may be accomplished by a variety of processes, including electroplating, sputtering, or chemical vapor deposition (“CVD”) or electroless plating. Some processes may require a seed layer on a surface to be bonded. Some embodiments may require some patterning of the metal layer to form metal pads for bonding, although a metal portion (such as a nickel portion described in illustrative embodiments) need not be a pad, and could take other forms.

The metal portion need not be formed directly on the member to be bonded; there may be one or more intermediate layers between the nickel and the member to be bonded. For example, a layer of aluminum may be fabricated on a member to be bonded, and a nickel layer fabricated on the aluminum layer.

In electroless plating, a metal, such as nickel, grows on an aluminum surface submersed in a bath of nickel hypophosphite, Ni(H2PO2)2 solution. In such a process, the nickel selectively grows only on the aluminum, so once the aluminum is fabricated (e.g., patterned), nickel will grow on that pattern and only on that pattern, without requiring additional patterning. Forming a nickel portion by means of electroless plating is advantageous in that it forms the nickel portion relatively quickly (on the order of 6 microns/hour), allows the location of the nickel portion to be tightly controlled, and does not require the application of a voltage to the nickel portion.

Some embodiments employ electroless plating because, for example, electroless plating can selectively deposit the metal without the need for patterning of the metal, and can be done at relatively low temperatures (for example, below 300 degrees Celsius) and pressures (for example, at approximately 50 MPa), as compared, for example, to aluminum-aluminum bonding.

If using nickel to form a silicide bond, the nickel as well as the silicon may oxidize if exposed to an environment containing oxygen. Bonding with nickel and silicon may therefore be deemed undesirable to those skilled in the art. Nevertheless, bonding may still be possible at temperatures low enough to protect integrated circuits or MEMS structures if sufficient pressure is applied to the bonding point. However, such increased pressure may be undesirable, for example if a MEMS device subjected to the pressure.

Such oxidation may be avoided by, for example, performing the fabrication and bonding in an ambient atmosphere that is substantially free of oxygen, or in an ambient atmosphere that includes elements or molecules that react with, and thereby effectively consume, the available oxygen. For example, an atmosphere within the bonding chamber of mostly nitrogen and one to five or six percent hydrogen may be sufficient.

Alternately, fabricating a film of gold on the surface of the nickel portions will mitigate the oxidation. For example, a gold layer of 300 Angstroms will deter oxidation, and will diffuse away after bonding. Alternately, gold itself may form the metal portion.

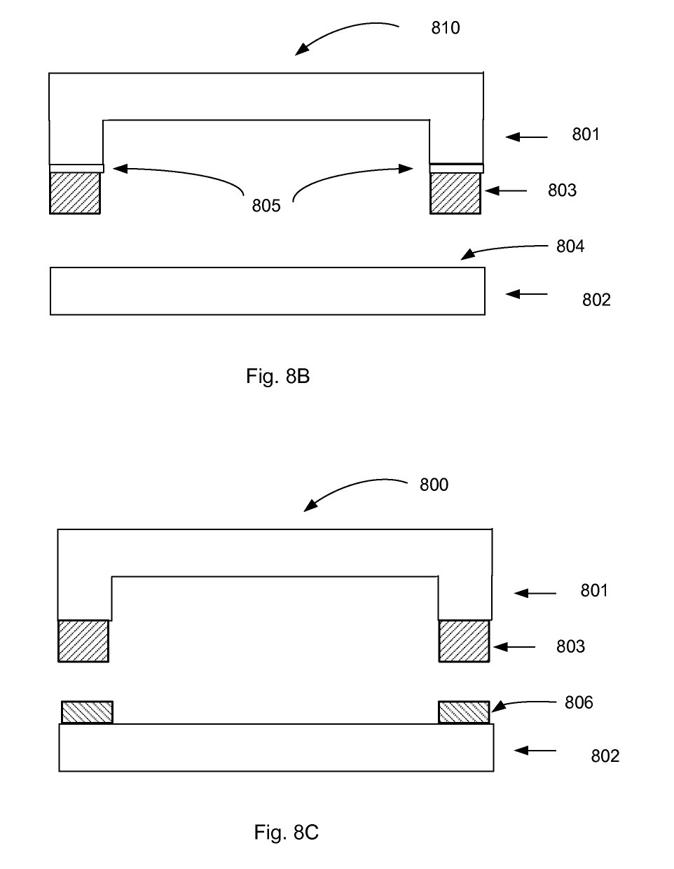

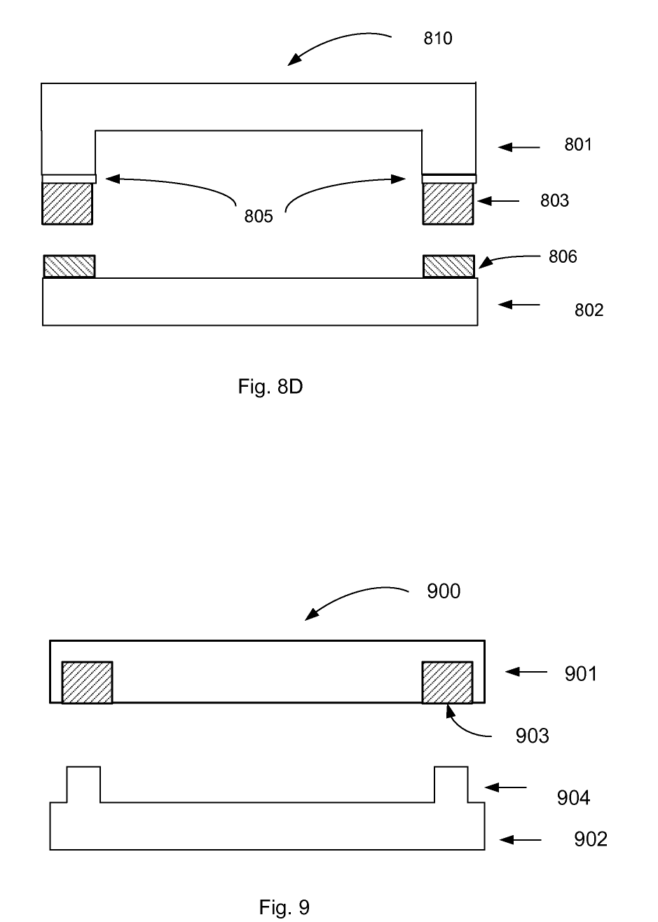

One embodiment of the present invention involves fabricating a nickel pad on one member, for use in forming a nickel silicide, as shown in the schematic cross-section 800 of FIG. 8A. In this embodiment, a first wafer 801 is a cap wafer that has a nickel pad 803 fabricated on its bottom surface. The nickel pad 803 can be coupled to an opposing silicon area 804, at a temperature and a pressure as described above, to form the nickel-silicide bond. In this embodiment, the members 801 and 802 may be bonded to form a cavity defined by the members, and the nickel-silicide bond. Such a cavity may be useful, for example, in wafer-level capping of a MEMS device.

Another embodiment of the present invention involves fabricating an aluminum portion 805 supported by the bottom surface 803 of first wafer 801, and forming the nickel portion 803 substantially on the aluminum portion, as shown in the schematic cross-section 810 of FIG. 8B.

Some embodiments may include a silicon area 806 on the second member to be bonded, as schematically illustrated in FIG. 8C and FIG. 8D.

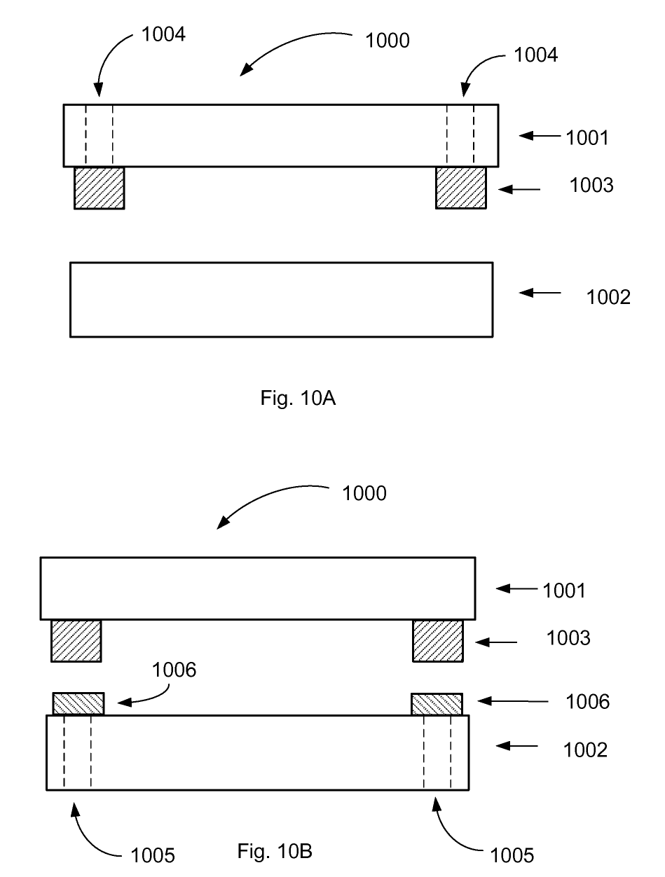

In some embodiments, the wafers may include vias, as schematically illustrated in FIG. 10A and FIG. 10B, for example.

An alternate embodiment may have a nickel portion formed within a first wafer, as schematically illustrated in cross-section 900 by nickel portion 903 in wafer 901 in FIG. 9. In some embodiments, the second wafer 902 may include a silicon portion 904 placed to couple with the nickel portion 903.

An alternate embodiment may include a nickel portion on a wafer at the end of a via through the wafer, so that the nickel portion acts as a contact for the via, as schematically illustrated in cross-section 1000 by nickel portion 1003 on wafer 1001 with via 1004, in FIG. 10A. Coupling wafers, such as wafers 1001 and 1002, may form stacks of wafers with two or more layers, in which the nickel-silicide may bond the wafers together, and may also provide an electrical interconnect to provide power, ground, or a signal line through the various wafers.

In some embodiments, a silicon portion 1006 may be included on the opposing wafer 1002, as in FIG. 10B. In some embodiments, the opposing wafer may also include vias 1005 in the wafer 1002 and contacting the silicon portion 1006 so that the silicon portion acts as a contact for the via. A variety of arrangements of nickel, aluminum and silicon areas may be implemented with vias through at least one of the wafers, similar to the arrangements in FIG. 8A through 8D, for example.

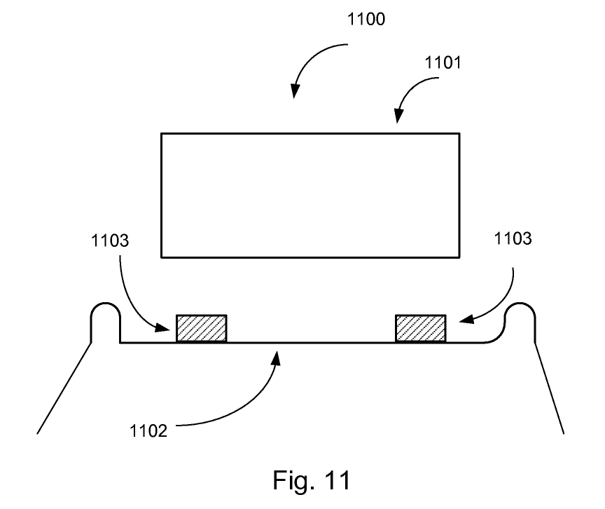

An alternate embodiment may form a nickel-silicide to bond a member 1101 (such as an integrated circuit, for example) to a lead frame 1102, as schematically illustrated in cross-section 1100 in FIG. 11. The nickel portion 1103 may be formed on the lead frame 1102, and the nickel-silicide bond may be formed by coupling silicon integrated circuit 1101 to the nickel portions 1103 at a selected temperature and pressure. Such a bond may be used to bond a member to a variety of surfaces, such as ceramic, or a printed circuit board, for example.

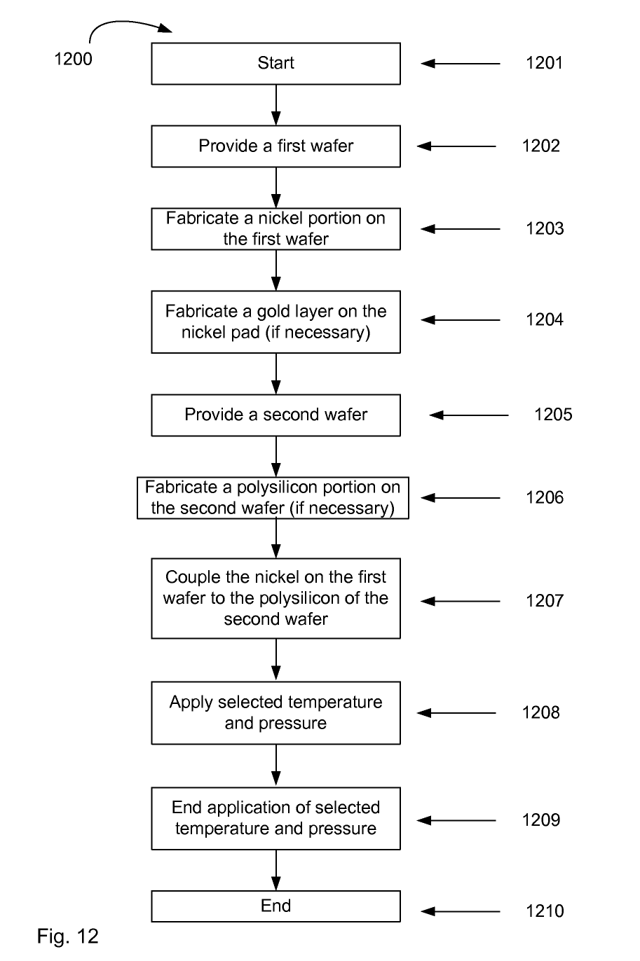

A flow chart 1200 for bonding two members according to one embodiment of the present invention is shown in FIG. 12. A first wafer is provided (1202), and may already include a nickel layer or nickel portions in desired locations. If not, or if additional nickel portions are desired, one or more nickel portions may be fabricated on the first wafer (1203). If the formation of an oxide layer on the nickel is a concern, a gold layer may be fabricated on the nickel portion (1204). A second wafer is provided (1205) to be bonded to the first wafer by formation of a nickel-silicide. If polysilicon portions are desired on the second wafer, they may be fabricated on the second wafer (1206). Then, the nickel portions of the first wafer are physically coupled to the polysilicon portions of the second wafer (1207) at a selected temperature (in some embodiments, at about 450 degrees Celsius, while in other embodiments below 300 degrees Celsius or even below 280 degrees Celsius) and pressure (preferably below 50 MPa) to cause the nickel portions and the polysilicon portions to form nickel silicide bonds (1208). After a predetermined time, which will depend on the temperature and pressure selected, the temperature is lowered and the pressure is released (1209), to complete the formation of the nickel silicide bond (1210). Selection of the temperatures and pressures must be determined according to the metal being used, and the requirements (such as temperature and pressure limitations) of the members being bonded.

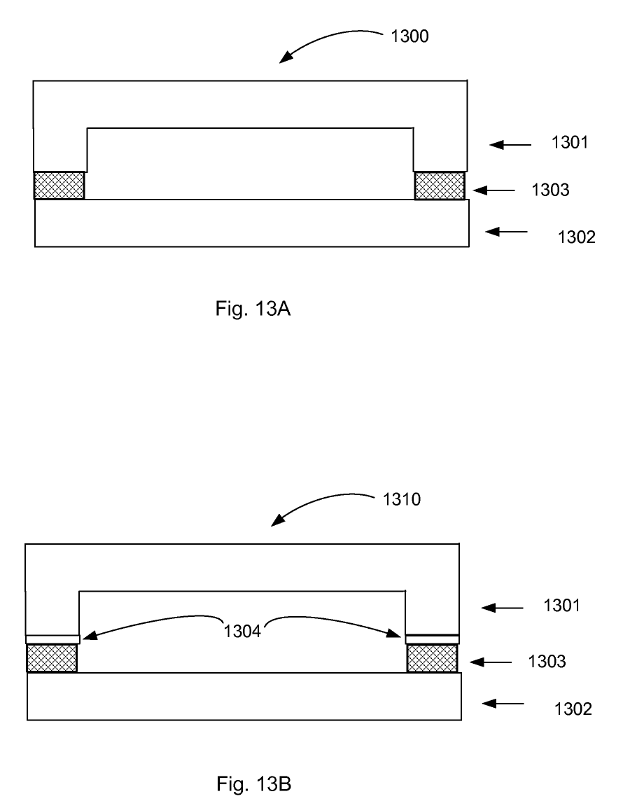

A device 1300 fabricated according to one embodiment is schematically illustrated in FIG. 13A, in which a coupling member 1301 and a silicon member 1302 (for example, a die or wafer) are bonded by a nickel silicide, illustrated as structure 1303.

A device 1310 fabricated according to another embodiment is schematically illustrated in FIG. 13B, in which a coupling member 1301 includes an aluminum portion 1304. The coupling member 1301 and a silicon member 1302 are bonded by a nickel silicide, illustrated as structure 1303, in which the aluminum portion 1304 is disposed in-between the coupling member 1301 and the nickel silicide 1303.

The embodiments of the invention described above are intended to be merely exemplary; numerous variations and modifications will be apparent to those skilled in the art. All such variations and modifications are intended to be within the scope of the present invention as defined in any appended claims.

What is claimed is:

1. A method of bonding a first surface to a second surface, the method comprising:
providing a first surface having a nickel portion;
providing a second surface having a silicon portion;
contacting the first surface and the second surface so that the nickel portion contacts the silicon portion;
subjecting the nickel portion and the silicon portion to a temperature of no greater than about 450 degrees Celsius; and
providing a compressive force at the interface of the nickel portion and the silicon portion;
wherein the temperature and compressive force are sufficient to form nickel silicide at the interface of the nickel portion and the silicon portion.

2. A method according to claim 1 wherein providing a first surface having a nickel portion comprises forming a nickel portion on the first surface by a process of electroless plating.

3. A method according to claim 1 wherein providing a first surface having a nickel portion comprises forming a nickel portion on the first surface by a process of electroplating.

4. A method according to claim 1 wherein providing a first surface having a nickel portion comprises forming a nickel portion on the first surface by a process of physical vapor deposition.

5. A method according to claim 1 wherein providing a first surface having a nickel portion comprises forming a nickel portion on the first surface by a process of chemical vapor deposition.

6. A method according to claim 1 wherein providing a first surface having a nickel portion comprises forming an aluminum portion supported by the first surface, and forming the nickel portion substantially on the aluminum portion.

7. A method according to claim 1 wherein providing a first surface having a nickel portion comprises forming a layer of gold over at least part of the nickel portion.

8. A method according to claim 1 wherein providing a first surface having a nickel portion comprises forming the nickel portion on the first surface in a substantially oxygen-free environment.

9. A method according to claim 1 wherein one of the first surface and the second surface comprises a leadframe for a semiconductor die.

10. A method according to claim 1 wherein providing a second surface having a silicon portion comprises forming a silicon portion on the second surface.

11. A method according to claim 1 wherein forming a silicon portion comprises forming a polysilicon pad.

12. A method according to claim 1 wherein subjecting the nickel portion and the silicon portion to a temperature of no greater than about 450 degrees Celsius further comprises subjecting the nickel portion and the silicon portion to a temperature less than 300 degrees Celsius.

13. A method of fabricating a semiconductor structure, the method comprising:
providing a first member;
fabricating a nickel pad on the first member;
providing a semiconductor member;
coupling the nickel pad to the semiconductor member; and
subjecting the nickel pad and the semiconductor member to a temperature less than about 450 degrees Celsius,
wherein the temperature at least in part is sufficient to form a silicide at the interface of the nickel pad and the semiconductor member.

14. A method of fabricating a semiconductor structure according to claim 13, wherein the semiconductor member includes a via, and wherein the nickel pad contacts the via.

15. A method of fabricating a semiconductor structure according to claim 13, wherein the semiconductor member comprises a cap.

16. A method of fabricating a semiconductor structure according to claim 13, wherein the first member comprises a leadframe.

17. A method of fabricating a semiconductor structure according to claim 13, wherein providing a semiconductor member further comprises forming a silicon pad on the semiconductor member.

18. A method of fabricating a semiconductor structure according to claim 13, further comprising forming a layer of gold on the nickel pad.

19. A semiconductor apparatus comprising:
a silicon member;
a coupling member having a surface; and
nickel silicide bonding the surface of the coupling member to the silicon member.

20. The semiconductor apparatus as defined by claim 19 wherein the surface has metal thereon.

21. The semiconductor apparatus as defined by claim 19 wherein the silicon member comprises a die or a wafer.
